(19) United States
(12) Patent Application Publication
(10) Pub. No.: US 2024/0243019 A1
(43) Pub. Date: Jul. 18, 2024

(54) SUBSTRATE PROCESSING APPARATUS, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Yuichiro TAKESHIMA, Toyama-shi (JP); Masanori Nakayama, Toyama-shi (JP); Yasutoshi Tsubota, Toyama-shi (JP); Hiroto Igawa, Toyama-shi (JP); Yuki Yamakado, Toyama-shi (JP); Hiroki Kishimoto, Toyama-shi (JP)

(73) Assignee: Kokusai Electric Corporation, Tokyo (JP)

(21) Appl. No.: 18/403,818

(22) Filed: Jan. 4, 2024

(30) Foreign Application Priority Data
Jan. 16, 2023 (JP) 2023-004743

(51) Int. Cl. H01L 21/66; H01J 37/32

(52) U.S. Cl. CPC H01L 22/26; H01J 37/32935; H01J 37/3299; H01J 2237/24585; H01J 2237/24592

(57) ABSTRACT

To suppress fluctuations in substrate processing results over time due to operations of a substrate processing apparatus, there is provided a technique that includes: a transfer chamber where a substrate is transferred; a process chamber in which the substrate is processed under process conditions of the substrate; a measurer for measuring a mass of the substrate before the processing of the substrate starts and after the processing of the substrate ends; a calculator for calculating a film thickness value of the substrate from a difference in the mass measured by the measurer before the processing starts and after the processing ends; a determinator for determining whether the film thickness value calculated by the calculator is abnormal; a setter for setting the process conditions; and a controller for controlling the setter to change the process conditions when the determinator determines that the film thickness value is abnormal.

### CROSS-REFERENCE TO RELATED PATENT APPLICATION

This non-provisional U.S. patent application is based on and claims priority under 35 U.S.C. § 119 of Japanese Patent Application No. 2023-004743, filed on Jan. 16, 2023, in the Japanese Patent Office, the entire contents of which are hereby incorporated by reference.

### BACKGROUND

### 1. Field

The present disclosure relates to a substrate processing apparatus, a method of manufacturing a semiconductor device and a non-transitory computer-readable recording medium.

### 2. Related Art

A substrate processing apparatus capable of performing a plasma treatment process on a substrate in a gas atmosphere such as a nitrogen atmosphere or an oxygen atmosphere may be used.

Further, in the substrate processing apparatus, a cover of a substrate mounting table (susceptor cover) provided with a heater may also be used. In such a case, when the substrate is processed (that is, a substrate processing is performed), a thermal emissivity of the susceptor cover may change. Thereby, processing results for the substrate may be affected. Specifically, with respect to a film formed on the substrate, a thickness of the film may increase over time.

### SUMMARY

According to the present disclosure, there is provided a technique capable of suppressing fluctuations in substrate processing results over time due to operations of a substrate processing apparatus.

According to one embodiment of the present disclosure, there is provided a technique that includes: a transfer chamber to which or from which a substrate is transferred; a process chamber in which a processing of the substrate is performed in accordance with process conditions of the substrate; a measurer configured to measure a mass of the substrate before the processing of the substrate starts and after the processing of the substrate ends; a calculator configured to calculate a film thickness value of the substrate from a difference in the mass measured by the measurer before the processing starts and after the processing ends; a determinator configured to determine whether the film thickness value calculated by the calculator is abnormal; a setter configured to set the process conditions; and a controller configured to be capable of controlling the setter to change the process conditions when the determinator determines that the film thickness value is abnormal.

### BRIEF DESCRIPTION OF THE DRAWINGS

FIG. 1 is a diagram schematically illustrating a substrate processing apparatus, when viewed from above, according to one or more embodiments of the present disclosure.

FIG. 2 is a diagram schematically illustrating a vertical cross-section of a PM1 (which is a process module) of the substrate processing apparatus according to the embodiments of the present disclosure.

FIG. 3 is a block diagram schematically illustrating a configuration of a controller and related components of the substrate processing apparatus according to the embodiments of the present disclosure.

FIG. 4 is a flow chart schematically illustrating a substrate processing according to the embodiments of the present disclosure.

FIG. 5 is a flow chart schematically illustrating a process flow from obtaining a mass of a substrate to changing process conditions of the substrate in the substrate processing according to the embodiments of the present disclosure.

### DETAILED DESCRIPTION

### Embodiments of Present Disclosure

Hereinafter, one or more embodiments (also simply referred to as “embodiments”) of the technique of the present disclosure will be described in detail with reference to the drawings. In the following descriptions of the embodiments, the same or similar reference numerals represent the same or similar components in the drawings, and redundant descriptions related thereto will be omitted. In addition, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match. In addition, the number of each component described in the present specification is not limited to one, and the number of each component described in the present specification may be two or more unless otherwise specified in the present specification.

### (1) Configuration of Substrate Processing Apparatus

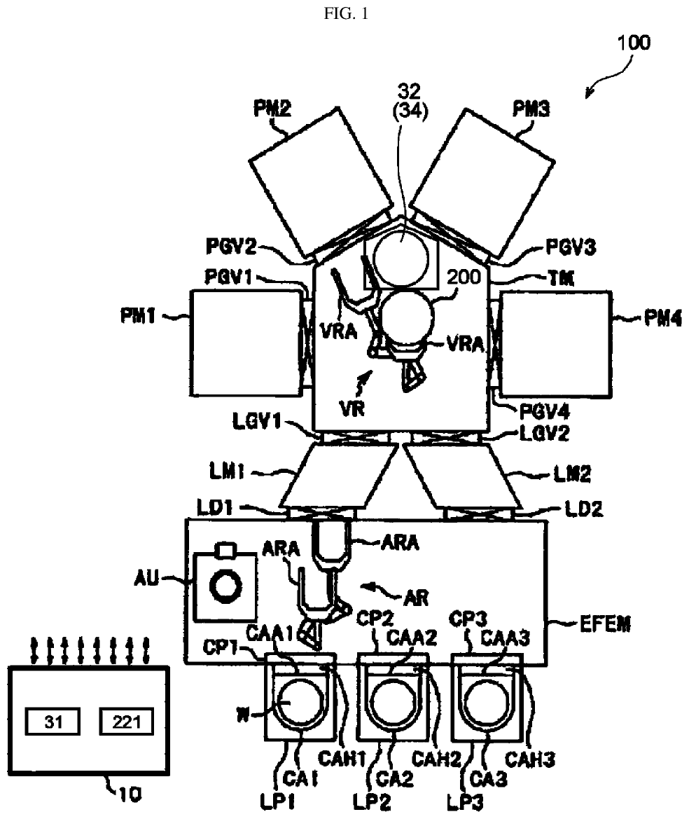

A substrate processing apparatus 100 according to the present embodiments of the technique of the present disclosure will be described with reference to FIGS. 1 through 5. For example, the substrate processing apparatus 100 includes: a vacuum transfer chamber TM serving as an example of a transfer chamber; a process chamber 201; a measurer (which is a measuring structure) 31c; a calculator 226; a determinator (which is a determining structure) 228; a setter (which is a setting structure) 227; and a controller 10. FIG. 1 is a diagram schematically illustrating the substrate processing apparatus 100, when viewed from above, according to the present embodiments.

The substrate processing apparatus 100 shown in FIG. 1 includes a vacuum side configuration of handling a substrate (for example, a wafer 200 made of a material such as silicon) in a reduced pressure state and an atmospheric pressure side configuration of handling the wafer 200 in an atmospheric pressure state. The vacuum side configuration mainly includes a vacuum transfer chamber TM, load lock chambers LM1 and LM2 and process modules (which are processing structures) PM1, PM2, PM3 and PM4 capable of processing the wafer 200. The atmospheric pressure side configuration mainly includes an atmospheric pressure transfer chamber EFEM and loading port structures LP1, LP2 and LP3. Carriers CA1, CA2 and CA3 capable of accommodating a plurality of wafers including the wafer 200 are transferred and placed on the loading port structures LP1 through LP3, respectively, from an outside of the substrate processing apparatus 100, and are also transferred to the outside of the substrate processing apparatus 100 from the loading port structures LP1 through LP3, respectively. Hereinafter, the plurality of wafers including the wafer 200 may also be simply referred to as “wafers 200”. With such a configuration, for example, the wafer 200 (which is unprocessed) is taken out from the carrier CA1 placed on the loading port structure LP1, loaded (transferred) into the process module PM1 through the load lock chamber LM1 and processed in the process module PM1. Then, the wafer 200 (which is processed) is returned to the carrier CA1 on the loading port structure LP1 in an order reverse to that described above. In a manner described above, for example, the wafer 200 can be transferred into the vacuum transfer chamber TM of the vacuum side configuration, into the atmospheric pressure transfer chamber EFEM of the atmospheric pressure side configuration, and also between the vacuum transfer chamber TM and the atmospheric pressure transfer chamber EFEM.

### <Vacuum Side Configuration>

The vacuum transfer chamber TM is configured as a vacuum airtight structure capable of withstanding a negative pressure (which is a reduced pressure) below an atmospheric pressure such as a pressure in a vacuum state. Further, according to the present embodiments, for example, a housing of the vacuum transfer chamber TM is pentagonal when viewed from above. The housing is of a box shape with closed upper and lower ends in a vertical direction. The load lock chambers LM1 and LM2 and the process modules PM1 through PM4 are arranged so as to surround an outer periphery of the vacuum transfer chamber TM. In the present specification, unless the process modules PM1 through PM4 need to be distinguished separately, the process modules PM1 through PM4 may be collectively or individually referred to as a “process module PM”. In addition, unless the load lock chambers LM1 and LM2 need to be distinguished separately, the load lock chambers LM1 and LM2 may be collectively or individually referred to as a “load lock chambers LM”. The same also applies to other configurations such as a vacuum robot VR and an arm VRA, which will be described later.

For example, the vacuum robot VR is provided in the vacuum transfer chamber TM. The vacuum robot VR serves as a transfer structure capable of transferring the wafer 200 in the reduced pressure state. The vacuum robot VR is configured to transfer the wafer 200 between the load lock chamber LM and the process module PM by placing the wafer 200 on two sets of substrate support arms VRA (hereinafter, may also be referred to as the “arm VRA”) serving as substrate placement structures. Further, the vacuum robot VR is configured to be elevated or lowered in the vertical direction while maintaining an airtightness of the vacuum transfer chamber TM. In addition, the two sets of the arm VRA are separated in the vertical direction. Each of the two sets of the arm VRA is configured to be capable of being expanded and contracted in a horizontal direction and being rotationally moved in a horizontal plane.

For example, each process module PM includes a substrate mounting structure on which the wafer 200 is placed. For example, each process module PM is configured as a single wafer type process chamber in which the wafers 200 are processed one by one in the reduced pressure state. That is, each process module PM serves as the single wafer type process chamber in which a process (for example, an etching process using a plasma or the like, an ashing process or a film-forming process by a chemical reaction) is performed to the wafer 200 to provide added values to the wafer 200.

The process module PM (that is, the process modules PM1 through PM4) is connected to the vacuum transfer chamber TM by a gate valve PGV (that is, gate valves PGV1, PGV2, PGV3 and PGV4) serving as an opening/closing valve. As a result, the process module PM can transfer the wafer 200 to and from the vacuum transfer chamber TM under the reduced pressure state by opening the gate valve PGV. Further, by closing the gate valve PGV, the process module PM can perform various processes such as a substrate processing on the wafer 200 while maintaining an inner pressure of the process module PM to a desired pressure and an inner atmosphere of the process module PM to a process gas atmosphere.

The load lock chamber LM functions as a spare chamber through which the wafer 200 is transferred into the vacuum transfer chamber TM or as a spare chamber through which the wafer 200 is transferred out of the vacuum transfer chamber TM. Buffer stages (not shown) serving as substrate placement structures configured to temporarily support the wafer 200 when the wafer 200 is transferred into or out of the vacuum transfer chamber TM are provided in the load lock chamber LM (that is, the load lock chambers LM1 and LM2, respectively). Each of the buffer stages may be configured as a multi-stage type slot capable of supporting a predetermined number of wafers (for example, two wafers) including the wafer 200.

Further, the load lock chamber LM (that is, the load lock chambers LM1 and LM2) is connected to the vacuum transfer chamber TM by a gate valve LGV (that is, gate valves LGV1 and LGV2) serving as an opening/closing valve. Further, the load lock chamber LM is connected to the atmospheric pressure transfer chamber EFEM, which will be described later, by a gate valve LD (that is, gate valves LD1 and LD2) serving as an opening/closing valve. By closing the gate valve LGV provided corresponding to the vacuum transfer chamber TM and opening the gate valve LD provided corresponding to the atmospheric pressure transfer chamber EFEM, it is possible to transfer the wafer 200 between the load lock chamber LM and the atmospheric pressure transfer chamber EFEM under the atmospheric pressure while maintaining a vacuum airtightness in the vacuum transfer chamber TM.

Further, the load lock chamber LM is configured as a vacuum airtight structure capable of withstanding the negative pressure (which is the reduced pressure) below the atmospheric pressure such as the pressure in the vacuum state, and is configured such that an inner atmosphere of the load lock chamber LM can be vacuum-exhausted. Thereby, after the gate valve LD provided corresponding to the atmospheric pressure transfer chamber EFEM is closed and the inner atmosphere of the load lock chamber LM is vacuum-exhausted, the gate valve LGV provided corresponding to the vacuum transfer chamber TM is opened. As a result, it is possible to transfer the wafer 200 between the load lock chamber LM and the vacuum transfer chamber TM under the reduced pressure state while maintaining the vacuum airtightness (vacuum state) in the vacuum transfer chamber TM. In a manner as described above, the load lock chamber LM is configured to be capable of being switched between the atmospheric pressure state and the reduced pressure state.

### <Atmospheric Pressure Side Configuration>

On the other hand, as described above, (i) the atmospheric pressure transfer chamber EFEM (Equipment Front End Module) serving as a front module connected to the load lock chambers LM1 and LM2 and (ii) the loading port structures LP1 through LP3 connected to the atmospheric pressure transfer chamber EFEM and serving as carrier placement structures on which the carriers CA1 through CA3 can be placed are provided at an atmospheric pressure portion of the substrate processing apparatus 100. For example, each of the carriers CA1 through CA3 serves as a substrate storage container in which the wafers 200 corresponding to a single lot (for example, 25 wafers) can be stored. As each of the carriers CA1 through CA3, for example, a FOUP (Front Opening Unified Pod) may be used. In the present specification, the loading port structures LP1 through LP3 may be collectively or individually referred to as a “loading port structure LP”. That is, the loading port structure LP may be referred to as a representative of the loading port structures LP1 through LP3. In addition, the carriers CA1 through CA3 may be collectively or individually referred to as a “carrier CA”. That is, the carrier CA may be referred to as a representative of the carriers CA1 through CA3. Similar to the vacuum side configuration, the same also applies to other configurations (such as carrier doors CAH1, CAH2 and CAH3 and carrier openers CP1, CP2 and CP3, which will be described later) of the atmospheric pressure side configuration.

For example, an atmospheric pressure robot AR serving as a transfer structure is provided in the atmospheric pressure transfer chamber EFEM. The atmospheric pressure robot AR is configured to transfer the wafer 200 between the load lock chamber LM1 and the carrier CA on the loading port structure LP1. Similar to the vacuum robot VR, the atmospheric pressure robot AR is also provided with two sets of arms ARA serving as substrate placement structures.

The carrier CA is provided with a carrier door CAH which serves as a cap (lid) of the carrier CA. For example, with the carrier door CAH of the carrier CA installed on the loading port structure LP open, the wafer 200 may be accommodated in the carrier CA by the atmospheric pressure robot AR through a substrate loading/unloading port CAA (that is, substrate loading/unloading ports CAA1, CAA2 and CAA3), or the wafer 200 in the carrier CA may be transferred out of the carrier CA by the atmospheric pressure robot AR.

Further, in the atmospheric pressure transfer chamber EFEM, a carrier opener CP capable of opening and closing the carrier door CAH is provided corresponding to the loading port structure LP. That is, an inside of the atmospheric pressure transfer chamber EFEM is connected to the loading port structure LP via the carrier opener CP.

The carrier opener CP includes a closure capable of being in close contact with the carrier door CAH and a driver (which is a driving structure) capable of operating the closure in the horizontal direction and the vertical direction. The carrier opener CP is configured to open and close the carrier door CAH by moving the closure in the horizontal direction and the vertical direction together with the carrier door CAH while maintaining the closure in close contact with the carrier door CAH.

For example, in the atmospheric pressure transfer chamber EFEM, an aligner AU, which is an orientation flat alignment device capable of aligning a crystal orientation of the wafer 200, is provided as a substrate position correction device. In addition, the atmospheric pressure transfer chamber EFEM is provided with a clean air supplier (which is a clean air supply structure or a clean air supply system) (not shown) through which clean air is supplied into the atmospheric pressure transfer chamber EFEM.

The loading port structure LP is configured to place each of the carriers CA1 through CA3 accommodating the wafers 200 on the loading port structure LP. In each carrier CA, slots (not shown) serving as a storage structure capable of accommodating the wafers 200 are provided. For example, 25 slots corresponding to the single lot are provided. When the carrier CA is placed, each loading port structure LP is configured to read and store a bar code or the like attached to the carrier CA and indicating a carrier ID used to identify the carrier CA.

Subsequently, the controller 10 configured to collectively control the substrate processing apparatus 100 will be described. The controller 10 is configured to control components constituting the substrate processing apparatus 100. The controller 10 includes at least a transfer system controller 31 serving as a transfer control structure and a process system controller 221 serving as a process control structure described later.

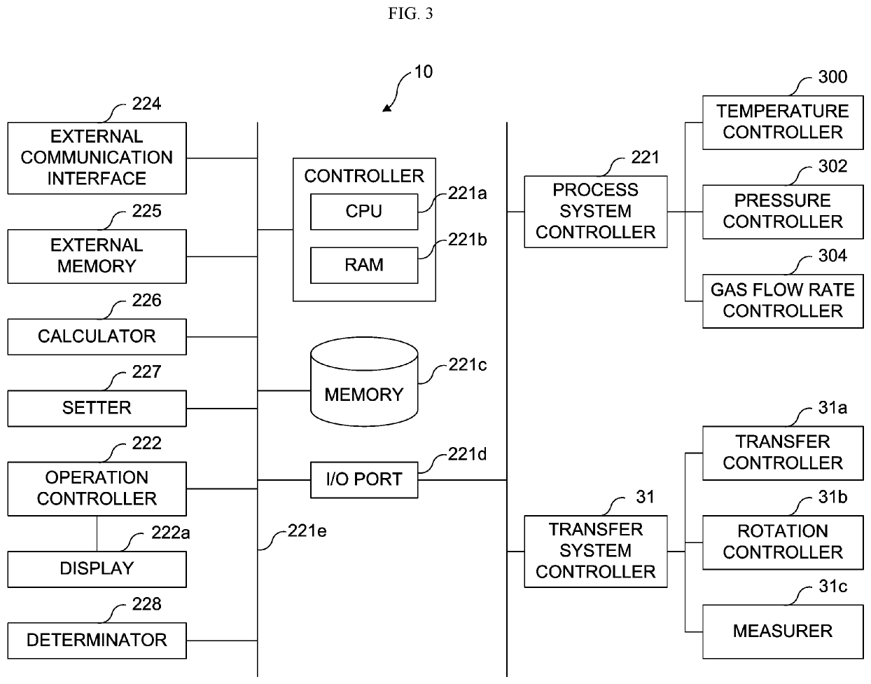

The controller 10 includes an operation controller 222 and a display (which is a display structure) 222a (see FIG. 3). The controller 10 is configured to receive an operation or an instruction by an operating personnel via the operation controller 222 and the display 222a. Information such as an operation screen and various data is displayed on the display 222a. The data displayed on the display 222a is stored in a memory 221c (see FIG. 3).

The transfer system controller 31 includes a robot controller configured to control the vacuum robot VR and the atmospheric pressure robot AR. The transfer system controller 31 is configured to perform a transfer control of the wafer 200 and to control an execution of a work instructed by the operating personnel. For example, the robot controller (that is, the transfer system controller 31) includes a transfer controller 31a and a rotation controller 31b. Further, the transfer system controller 31 further includes the measurer 31c (described later) configured to measure a mass of the wafer 200 before a processing of the wafer 200 starts and after the processing of the wafer 200 ends.

For example, based on a transfer recipe created or edited by the operating personnel via the operation controller 222, the transfer system controller 31 is configured to output control data (control instruction) when the wafer 200 is transferred to the components such the vacuum robot VR, the atmospheric pressure robot AR, various valves and switches. Then, the transfer system controller 31 performs the transfer control of the wafer 200 inside the substrate processing apparatus 100.

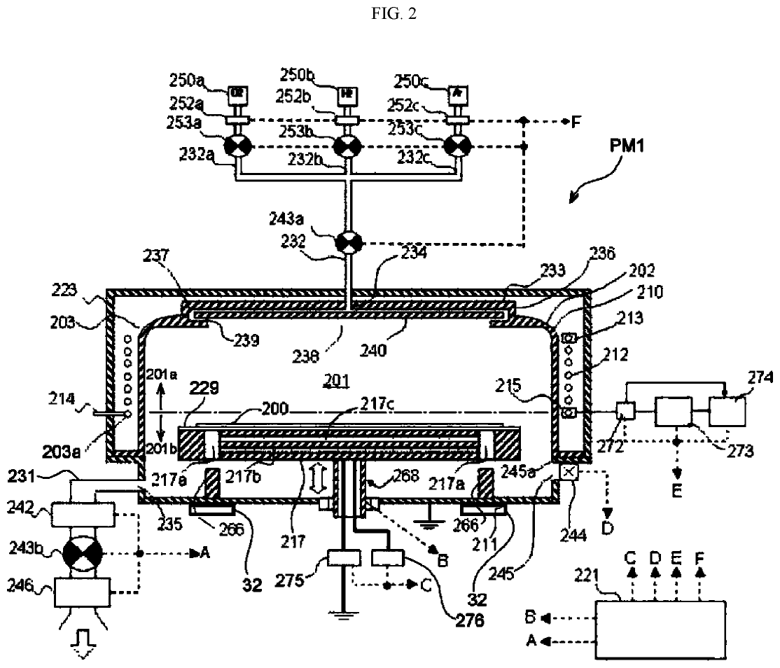

As shown in FIG. 2, the process system controller 221 is configured to control various components (which will be described later) such as: an APC valve 242, a valve 243b and a vacuum pump 246 through a signal line “A”; a susceptor elevator 268 through a signal line “B”; a heater power regulator 276 and a variable impedance regulator 275 through a signal line “C”; a gate valve 244 through a signal line “D”; an RF sensor 272, a high frequency power supply 273 and a matcher 274 through a signal line “E”; and MFCs 252a, 252b and 252c and valves 253a, 253b, 253c and 243a through a signal line “F”.

For example, based on a process recipe created or edited by the operating personnel via the operation controller 222, the process system controller 221 is configured to output control data (control instruction) when the wafer 200 is processed to the components such the various valves and the MFCs. Then, the process system controller 221 performs a substrate processing control of the wafer 200 inside the substrate processing apparatus 100.

As shown in FIG. 1, the controller 10 may be provided not only inside the substrate processing apparatus 100 but also outside the substrate processing apparatus 100. Further, the controller 10, the transfer system controller 31 and the process system controller 221 serving as the process control structure configured to control the process module PM may be constituted by a general purpose computer such as a PC (personal computer). In such a case, each of the controller 10, the transfer system controller 31 and the process system controller 221 may be configured by installing a program on the general purpose computer by using a computer-readable recording medium such as a USB memory and a DVD in which various programs are stored.

Further, a method of supplying the program for executing the process described above can be appropriately selected. Instead of or in addition to being supplied through a predetermined recording medium as described above, for example, the program may be provided through a communication line, a communication network or a communication system. In such a case, for example, the program may be posted on a bulletin board on the communication network, and may be provided by being superimposed on a carrier wave via the communication network. Further, the program provided as described above may be executed to perform the above-described process under control of an OS (operating system) of the substrate processing apparatus 100 just like any other application programs.

### <Process Chamber>

FIG. 2 is a diagram schematically illustrating a vertical cross-section of the process module PM1 of the substrate processing apparatus 100 according to the present embodiments. A configuration of each process module PM2, PM3 and PM4 is substantially the same as that of the process module PM1. The process module PM1 includes a process furnace 202 in which the wafer 200 serving as the substrate is processed by a plasma. A process vessel 203 constituting the process chamber 201 is provided in the process furnace 202. In the process chamber 201, the wafer 200 is processed (that is, the processing of the wafer 200 is performed) in accordance with process conditions of the wafer 200. The process vessel 203 includes an upper vessel 210 (which is dome-shaped) serving as a first vessel and a lower vessel 211 (which is bowl-shaped) serving as a second vessel. By covering the lower vessel 211 with the upper vessel 210, the process chamber 201 is defined. For example, the upper vessel 210 may be made of a non-metallic material such as aluminum oxide (Al₂O₃) or quartz (SiO₂), and the lower vessel 211 may be made of a material such as aluminum (Al).

In addition, the gate valve 244, which corresponds to the gate valve PGV (that is, the gate valves PGV1, PGV2, PGV3 and PGV4 shown in FIG. 1), is provided on a lower side wall of the lower vessel 211. While the gate valve 244 is open, the wafer 200 can be transferred (loaded) into the process chamber 201 through a loading/unloading port 245 using the transfer structure (that is, the vacuum robot VR shown in FIG. 1), or can be transferred (unloaded) out of the process chamber 201 through the loading/unloading port 245 using the transfer structure (that is, the vacuum robot VR shown in FIG. 1). While the gate valve 244 is closed, the gate valve 244 maintains the process chamber 201 airtight.

For example, the process chamber 201 includes a plasma generation space 201a and a substrate processing space 201b. A resonance coil 212 is provided around the plasma generation space 201a. The substrate processing space 201b communicates with the plasma generation space 201a, and the wafer 200 is processed in the substrate processing space 201b. The plasma generation space 201a refers to a space in which the plasma is generated, for example, a space above a lower end (indicated by a dash-dotted line in FIG. 2) of the resonance coil 212 and below an upper end of the resonance coil 212 in the process chamber 201. In addition, the substrate processing space 201b refers to a space in which the substrate (that is, the wafer 200) is processed by the plasma, for example, a space below the lower end of the resonance coil 212.

### <Susceptor 217>

A susceptor 217 serving as a part of substrate mounting table on which the wafer 200 is placed is provided at a center of a bottom of the process chamber 201. For example, the susceptor 217 is made of a non-metallic material such as aluminum nitride (AlN), ceramics and quartz, and is configured to be capable of reducing a metal contamination on a structure such as a film formed on the wafer 200.

A heater 217b serving as a heating structure is integrally embedded in the susceptor 217. When electric power is supplied to the heater 217b, the heater 217b is configured to heat a surface of the wafer 200 placed on the susceptor 217 such that the wafer 200 is heated to a predetermined temperature within a range from 25° C. to 700° C., for example.

The susceptor 217 is electrically insulated from the lower vessel 211. An impedance adjusting electrode 217c is provided in the susceptor 217. The impedance adjusting electrode 217c is grounded via the variable impedance regulator 275 serving as an impedance adjusting structure. For example, the variable impedance regulator 275 is constituted by components such as a coil (not shown) and a variable capacitor (not shown). The variable impedance regulator 275 is configured to change an impedance of the impedance adjusting electrode 217c within a range from about 0Ω to a parasitic impedance value of the process chamber 201 by controlling an inductance and resistance of the coil (not shown) and a capacitance value of the variable capacitor (not shown). Thereby, it is possible to control a potential (bias voltage) of the wafer 200 via the impedance adjusting electrode 217c and the susceptor 217.

The susceptor elevator 268 capable of elevating and lowering the susceptor 217 is provided at the susceptor 217. In addition, a plurality of through-holes 217a are provided at the susceptor 217, and a plurality of wafer lift pins 266 are provided at a bottom surface of the lower vessel 211 at locations corresponding to the plurality of through-holes 217a. For example, at least three of the through-holes 217a and at least three of the wafer lift pins 266 are provided at positions facing one another. When the susceptor 217 is lowered by the susceptor elevator 268, the wafer lift pins 266 pass through the through-holes 217a without contacting the susceptor 217.

The substrate mounting table (or the substrate support) according to the present embodiments is constituted mainly by the susceptor 217, the heater 217b and the impedance adjusting electrode 217c. A susceptor cover 229 is arranged on the susceptor 217, and the wafer 200 is placed on the susceptor cover 229. For example, the susceptor cover 229 is of a disk shape, and is made of a material such as silicon carbide (SiC).

### <Gas Supplier>

A shower head 236 is provided above the process chamber 201, that is, on an upper portion of the upper vessel 210. For example, the shower head 236 includes a cap-shaped lid 233, a gas inlet port 234, a buffer chamber 237, an opening 238, a shield plate 240 and a gas outlet port 239. In addition, the shower head 236 is configured such that a gas such as a reactive gas can be supplied into the process chamber 201 through the shower head 236. The buffer chamber 237 functions as a dispersion space in which the reactive gas introduced (supplied) through the gas inlet port 234 is dispersed.

A gas supply pipe 232 is connected to the gas inlet port 234. A downstream end of an oxygen-containing gas supply pipe 232a through which oxygen gas (O₂ gas) serving as an oxygen-containing gas is supplied, a downstream end of a hydrogen-containing gas supply pipe 232b through which hydrogen gas (H₂ gas) serving as a hydrogen-containing gas is supplied and a downstream end of an inert gas supply pipe 232c through which argon (Ar) gas serving as an inert gas is supplied are connected to the gas supply pipe 232 so as to be conjoined with one another. An O₂ gas supply source 250a, a mass flow controller (MFC) 252a serving as a flow rate controller and a valve 253a serving as an opening/closing valve are sequentially provided at the oxygen-containing gas supply pipe 232a in this order from an upstream side to a downstream side of the oxygen-containing gas supply pipe 232a in a gas flow direction. A H₂ gas supply source 250b, an MFC 252b serving as a flow rate controller and a valve 253b serving as an opening/closing valve are sequentially provided at the hydrogen-containing gas supply pipe 232b in this order from an upstream side to a downstream side of the hydrogen-containing gas supply pipe 232b in the gas flow direction. An Ar gas supply source 250c, an MFC 252c serving as a flow rate controller and a valve 253c serving as an opening/closing valve are sequentially provided at the inert gas supply pipe 232c in this order from an upstream side to a downstream side of the inert gas supply pipe 232c in the gas flow direction. A valve 243a is provided at the gas supply pipe 232 at a downstream side of a location where the oxygen-containing gas supply pipe 232a, the hydrogen-containing gas supply pipe 232b and the inert gas supply pipe 232c join. The valve 243a is connected to an upstream end of the gas inlet port 234. By opening and closing the valves 253a, 253b, 253c and 243a, it is possible to adjust flow rates of the oxygen-containing gas, the hydrogen-containing gas and the inert gas by the MFCs 252a, 252b and 252c, respectively. In addition, it is configured such that the reactive gas (that is, the oxygen-containing gas, the hydrogen-containing gas and the inert gas) can be supplied into the process chamber 201 through the oxygen-containing gas supply pipe 232a, the hydrogen-containing gas supply pipe 232b and the inert gas supply pipe 232c.

A gas supplier (which is a gas supply structure or a gas supply system) according to the present embodiments is constituted mainly by the shower head 236 (which is constituted by the lid 233, the gas inlet port 234, the buffer chamber 237, the opening 238, the shield plate 240 and the gas outlet port 239), the oxygen-containing gas supply pipe 232a, the hydrogen-containing gas supply pipe 232b, the inert gas supply pipe 232c, the MFCs 252a, 252b and 252c and the valves 253a, 253b, 253c and 243a.

For example, an oxygen-containing gas supplier (which is an oxygen-containing gas supply structure or an oxygen-containing gas supply system) according to the present embodiments is constituted mainly by the shower head 236 (which is constituted by the lid 233, the gas inlet port 234, the buffer chamber 237, the opening 238, the shield plate 240 and the gas outlet port 239), the oxygen-containing gas supply pipe 232a, the MFC 252a and the valves 253a and 243a.

For example, a hydrogen-containing gas supplier (which is a hydrogen-containing gas supply structure or a hydrogen-containing gas supply system) according to the present embodiments is constituted mainly by the shower head 236 (which is constituted by the lid 233, the gas inlet port 234, the buffer chamber 237, the opening 238, the shield plate 240 and the gas outlet port 239), the hydrogen-containing gas supply pipe 232b, the MFC 252b and the valves 253b and 243a.

For example, an inert gas supplier (which is an inert gas supply structure or an inert gas supply system) according to the present embodiments is constituted mainly by the shower head 236 (which is constituted by the lid 233, the gas inlet port 234, the buffer chamber 237, the opening 238, the shield plate 240 and the gas outlet port 239), the inert gas supply pipe 232c, the MFC 252c and the valves 253c and 243a.

For example, the gas supplier may further include the O₂ gas supply source 250a, the H₂ gas supply source 250b and the Ar gas supply source 250c. For example, the oxygen-containing gas supplier may further include the O₂ gas supply source 250a. For example, the hydrogen-containing gas supplier may further include the H₂ gas supply source 250b. For example, the inert gas supplier may further include the Ar gas supply source 250c.

### <Exhauster>

A gas exhaust port 235 through which the reactive gas is exhausted from an inside of the process chamber 201 is provided on a side wall of the lower vessel 211. An upstream end of a gas exhaust pipe 231 is connected to the gas exhaust port 235. The APC (Automatic Pressure Controller) valve 242 serving as a pressure regulator (pressure adjusting structure), the valve 243b serving as an opening/closing valve and the vacuum pump 246 serving as a vacuum exhaust apparatus are sequentially provided at the gas exhaust pipe 231 in this order from an upstream side to a downstream side of the gas exhaust pipe 231 in the gas flow direction.

An exhauster (which is an exhaust structure or an exhaust system) according to the present embodiments is constituted mainly by the gas exhaust port 235, the gas exhaust pipe 231, the APC valve 242 and the valve 243b. The exhauster may further include the vacuum pump 246.

### <Plasma Generator>

The resonance coil 212 of a helical shape is provided around an outer periphery of the process chamber 201, that is, around an outer portion of a side wall of the upper vessel 210 so as to surround the process chamber 201. The resonance coil 212 serves as a first electrode. The RF (Radio Frequency) sensor 272, the high frequency power supply 273 and the matcher (which is a frequency matching structure) 274 are connected to the resonance coil 212.

The high frequency power supply 273 is configured to supply a high frequency power to the resonance coil 212. The RF sensor 272 is provided at an output side of the high frequency power supply 273. The RF sensor 272 is configured to monitor information of the traveling wave or reflected wave of the high frequency power supplied from the high frequency power supply 273. The matcher 274 is configured to control the high frequency power supply 273 so as to minimize the reflected wave based on the information of the reflected wave monitored by the RF sensor 272.

A winding diameter, a winding pitch and the number of winding turns of the resonance coil 212 are set such that the resonance coil 212 resonates at a constant wavelength mode to form a standing wave of a predetermined wavelength. That is, an electrical length of the resonance coil 212 is set to an integral multiple (1 time, 2 times, or so on) of a wavelength of a predetermined frequency of the high frequency power supplied from the high frequency power supply 273. For example, a length of the wavelength is approximately 22 meters at 13.56 MHz, approximately 11 meters at 27.12 MHz and approximately 5.5 meters at 54.24 MHz. The resonance coil 212 is supported by a plurality of supports (not shown) of a flat plate shape made of an insulating material and vertically installed on an upper end surface of a base plate (not shown).

Further, both ends of the resonance coil 212 are electrically grounded. At least one end of the resonance coil 212 is grounded via a movable tap 213 in order to fine-tune the electrical length of the resonance coil 212 when the substrate processing apparatus 100 is newly installed or process conditions of the substrate processing apparatus 100 are changed. A reference numeral 214 shown in FIG. 2 indicates a fixed ground (grounded structure) at the other end of the resonance coil 212. Further, a power feeder (which is a power supply feeding structure) constituted by a movable tap 215 is provided between the grounded ends of the resonance coil 212 in order to fine-tune the impedance of the resonance coil 212 when the substrate processing apparatus 100 is newly installed or the process conditions of the substrate processing apparatus 100 are changed.

That is, the resonance coil 212 may include electrically grounded structures at both ends thereof and the power feeder to which the power is supplied from the high frequency power supply 273 between the grounded structures. In addition, one or both of the grounded structures may serve as a variable ground structure whose position can be adjusted, and the power feeder may serve as a variable power feeder whose position can be adjusted. When the resonance coil 212 includes the variable ground structure and the variable power feeder, it is possible to easily adjust a resonance frequency and a load impedance of the process chamber 201, as will be described later.

The shield plate 223 is provided to shield an electromagnetic wave from leaking to the outside of the resonance coil 212 and to form a capacitive component (also referred to as a “C component”) of the resonance coil 212 appropriate for constructing a resonance circuit between the shield plate 223 and the resonance coil 212. In general, the shield plate 223 is made of a conductive material such as an aluminum alloy, copper and a copper alloy, and is of a cylindrical shape. The shield plate 223 is disposed, for example, about 5 mm to 150 mm apart from an outer circumference of the resonance coil 212.

As described above, the RF sensor 272 is provided at the output side of the high frequency power supply 273. The RF sensor 272 is configured to monitor the information of the traveling wave or the reflected wave of the high frequency power. The power of the reflected wave monitored by the RF sensor 272 is input to the matcher 274. The matcher 274 is configured to control the frequency of the high frequency power output from the high frequency power supply 273 so as to minimize the reflected wave.

A plasma generator (which is a plasma generating structure) according to the present embodiment is constituted mainly by the resonance coil 212, the RF sensor 272 and the matcher 274. In addition, the plasma generator may further include the high frequency power supply 273. The winding diameter, the winding pitch and the number of winding turns of the resonance coil 212 are set such that the resonance coil 212 resonates at a full wavelength mode to form a standing wave of a predetermined wavelength. That is, the electrical length of the resonance coil 212 is set to an integral multiple (1 time, 2 times, or so on) of the wavelength of the predetermined frequency of the high frequency power supplied from the high frequency power supply 273.

Specifically, considering conditions such as the power to be applied, a strength of a magnetic field to be generated and a shape of an apparatus such as the substrate processing apparatus 100 to which the power is to be applied, the resonance coil 212 whose effective cross sectional area is within a range from 50 mm² to 300 mm² and whose diameter is within a range from 200 mm to 500 mm is wound, for example, twice to 60 times around an outer circumference of a room constituting the plasma generation space 201a such that the magnetic field of 0.01 G to 10 G can be generated by the high frequency power, whose frequency is within a range from 800 kHz to 50 MHz and whose power is within a range from 0.5 KW to 5 KW, being applied to the resonance coil 212. For example, a copper pipe, a copper thin plate, an aluminum pipe, an aluminum thin plate and a material obtained by depositing copper or aluminum on a polymer belt may be used as a material constituting the resonance coil 212.

For example, in general, one or both ends of the resonance coil 212 may be electrically grounded via the movable tap 213 in order to fine-tune the electrical length of the resonance coil 212 when the substrate processing apparatus 100 is newly installed and in order to adjust the resonance characteristics of the resonance coil 212 to be substantially the same as those of the high frequency power supply 273. Further, a waveform adjustment circuit (not shown) constituted by a coil (not shown) and a shield (not shown) is inserted into one end (or the other end or the both ends) of the resonance coil 212 such that a phase current thereof and an opposite phase current thereof flow symmetrically with respect to an electrical midpoint of the resonance coil 212. The waveform adjustment circuit is configured to be open by setting an end portion of the resonance coil 212 to an electrically disconnected state or an electrically equivalent state. In addition, an end portion of the resonance coil 212 may be non-grounded by a choke series resistor, or may be DC-connected to a fixed reference potential.

The shield plate 223 is provided to shield an electric field outside of the resonance coil 212 and to form the capacitive component (“C component”) of the resonance coil 212 appropriate for constructing the resonance circuit between the shield plate 223 and the resonance coil 212. In general, the shield plate 223 is made of a conductive material such as an aluminum alloy, copper and a copper alloy, and is of a cylindrical shape. The shield plate 223 is disposed, for example, about 5 mm to 150 mm apart from the outer circumference of the resonance coil 212. In general, the shield plate 223 is grounded such that a potential of the shield plate 223 is equal to those of both ends of the resonance coil 212. However, in order to accurately set the number of resonances of the resonance coil 212, one or both ends of the shield plate 223 may be configured such that a tap position of the shield plate 223 can be adjusted. Alternatively, in order to accurately set the number of the resonances, a trimming capacitance may be inserted between the shield plate 223 and the resonance coil 212.

The high frequency power supply 273 includes a power supply controller (which is a control circuit) (not shown) and an amplifier (which is an output circuit) (not shown). The power supply controller includes a high frequency oscillation circuit (not shown) and a preamplifier (not shown) in order to adjust an oscillation frequency and an output. The amplifier amplifies the output to a predetermined output level. The power supply controller controls the amplifier based on output conditions relating to the frequency and the power, which are set in advance through an operation panel (not shown), and the amplifier supplies a constant high frequency power to the resonance coil 212 via a transmission line.

A plasma generation circuit constituted by the resonance coil 212 is configured as an RLC parallel resonance circuit. When the wavelength of the high frequency power supplied from the high frequency power supply 273 and the electrical length of the resonance coil 212 are substantially the same, a resonance condition of the resonance coil 212 is that a reactance component generated by a capacitance component or an inductive component of the resonance coil 212 is canceled out to become a pure resistance. However, when the plasma is generated in the plasma generation circuit described above, an actual resonance frequency may fluctuate slightly depending on conditions such as a variation (change) in a capacitive coupling between a voltage portion of the resonance coil 212 and the plasma, a variation in an inductive coupling between the plasma generation space 201a and the plasma and an excitation state of the plasma.

Therefore, according to the present embodiments, in order to compensate for a resonance shift in the resonance coil 212 (which occurs when the plasma is generated) by adjusting the power supplied from the high frequency power supply 273, the matcher 274 is configured to correct an output of the high frequency power supply 273 based on the reflected wave power from the resonance coil 212 when the plasma is generated. With such a configuration, according to the present embodiments, it is possible to more accurately form the standing wave accurately in the resonance coil 212, and it is also possible to form the plasma whose capacitive coupling is extremely low.

That is, the matcher 274 detects the power of the reflected wave from the resonance coil 212 when the plasma is generated, and increases or decreases the oscillation frequency with respect to the predetermined frequency so that the power of the reflected wave is minimized. Specifically, the matcher 274 includes a frequency control circuit (not shown) capable of correcting a preset oscillation frequency. A reflected wave power meter, which serves as a part of the matcher 274, is provided at an output side of the amplifier in order to detect the power of the reflected wave via the transmission line and to feed back a voltage signal thereof to the frequency control circuit.

The frequency control circuit may include: an A/D converter configured to receive the voltage signal from the reflected wave power meter and to perform a digital conversion of the voltage signal into a frequency signal; an arithmetic processing circuit configured to perform an addition or subtraction processing of a value of the frequency signal (which corresponds to a converted reflected wave) and a value of the oscillation frequency (which is preset and stored in advance); a D/A converter configured to perform an analog conversion of a frequency value obtained by the addition or subtraction processing into another voltage signal; and a voltage controlled oscillator configured to perform an oscillation in accordance with an applied voltage from the D/A converter. Therefore, the frequency control circuit oscillates at a no-load resonance frequency of the resonance coil 212 before a plasma lighting and oscillates at a frequency that is increased or decreased from the predetermined frequency such that reflected power is minimized after the plasma lighting. As a result, the frequency signal is transmitted to the amplifier such that there is no reflected wave in the transmission line.

According to the present embodiments, for example, an inner pressure of the plasma generation space 201a is decreased to a pressure within a range from 0.01 Torr to 50 Torr, and then a plasma gas (the oxygen-containing gas in the present embodiments) is supplied to the plasma generation space 201a while maintaining a degree of vacuum. Further, for example, when the high frequency power of 27.12 MHz and 2 KW is supplied to the resonance coil 212 from the high frequency power supply 273, an induced electric field is generated in the plasma generation space 201a. As a result, the plasma gas supplied as described above is converted into a plasma state in the plasma generation space 201a.

The matcher 274 provided at the high frequency power supply 273 compensates for a deviation of a resonance point of the resonance coil 212 due to the variation in the capacitive coupling or the inductive coupling of the plasma by adjusting the power supplied from the high frequency power supply 273. That is, the RF sensor 272 of the matcher 274 detects the reflected wave power in accordance with the variation in the capacitive coupling or the inductive coupling of the plasma, decreases or increases the predetermined frequency by an extent that corresponds to a deviation of the resonance frequency causing the reflected wave power such that reflected wave power is minimized and outputs a high frequency of the resonance frequency of the resonance coil 212 to the amplifier under a plasma condition.

In other words, according to the present embodiments, the resonance coil 212 can more accurately form the standing wave since the high frequency power resonating accurately is output by compensating for the deviation of the resonance point in the resonance coil 212 when the plasma is generated and when the conditions for generating the plasma are changed. That is, as shown in FIG. 2, the standing wave in which a phase voltage thereof and an opposite phase voltage thereof are always canceled by each other is generated in the resonance coil 212 by the transmission of an actual resonance frequency of the resonance coil 212 reflecting the influence of the plasma, and the highest phase current is generated at the electrical midpoint of the resonance coil 212 (node with zero voltage). Therefore, an induction plasma excited at the electrical midpoint is almost not capacitively coupled with the walls of the process chamber 201 or the substrate mounting table. As a result, a donut-shaped plasma whose electric potential is extremely low can be generated in the plasma generation space 201a.

### <Controller>

As shown in FIG. 3, the controller 10 is connected to a computer including a CPU (Central Processing Unit) 221a, a RAM (Random Access Memory) 221b, the memory 221c and an I/O port 221d, or is constituted by the computer. The RAM 221b, the memory 221c and the I/O port 221d may exchange data with the CPU 221a through an internal bus 221e. For example, the operation controller 222 and the display 222a, which serve as an input/output device constituted by components such as a touch panel and a display, may be connected to the controller 10. Further, components such as an external communication interface 224, an external memory 225, the calculator 226, the setter 227 and the determinator 228 may be connected to the internal bus 221e.

The memory 221c may be constituted by a component such as a flash memory and a hard disk drive (HDD). For example, data such as a control program configured to control operations of the substrate processing apparatus 100 and a program recipe in which information such as sequences and conditions of the substrate processing described later is stored may be readably stored in the memory 221c. Various program recipes such as a process recipe (processing recipe) and a chamber condition recipe serving as a pre-processing recipe described later can be obtained by combining steps of the substrate processing described later such that the controller 10 can execute the steps to acquire a predetermined result, and functions as a program. Hereinafter, the program recipe and the control program may be collectively or individually referred to as a “program”. Thus, in the present specification, the term “program” may refer to the program recipe alone, may refer to the control program alone, or may refer to both of the program recipe and the control program. The RAM 221b functions as a memory area (work area) where a program or data read by the CPU 221a is temporarily stored.

The I/O port 221d is connected to the process system controller 221 and the transfer system controller 31. For example, as shown in FIG. 3, the process system controller 221 includes a temperature controller 300, a pressure controller 302 and a gas flow rate controller 304. As shown in FIG. 2, the temperature controller 300 is connected to the variable impedance regulator 275 and the heater power regulator 276 through the signal line C. The pressure controller 302 is connected to the valve 243b, the APC valve 242 and the vacuum pump 246 through the signal line A, and is connected to the gate valve 244 through the signal line D. The gas flow rate controller 304 is connected to the MFCs 252a, 252b and 252c and valves 253a, 253b, 253c and 243a through the signal line F. Further, the process system controller 221 is connected to the RF sensor 272, the high frequency power supply 273 and the matcher 274 through the signal line E, and is also connected to the susceptor elevator 268 through the signal line B.

The CPU 221a is configured to read and execute the control program stored in the memory 221c, and to read the process recipe stored in the memory 221c in accordance with an instruction such as an operation command inputted via the operation controller 222. The CPU 221a is configured to be capable of controlling the operations of the substrate processing apparatus 100 in accordance with the read process recipe. For example, the CPU 221a may be configured to be capable of controlling the operations such as an operation of adjusting an opening degree of the APC valve 242, an opening and closing operation of the valve 243b and a start and stop of the vacuum pump 246 via the process system controller 221, the I/O port 221d and the signal line A. Further, for example, the CPU 221a may be configured to be capable of controlling the operations such as an elevating and lowering operation of the susceptor elevator 268 via the process system controller 221, the I/O port 221d and the signal line B. Further, for example, the CPU 221a may be configured to be capable of controlling the operations such as a power supply amount adjusting operation (temperature adjusting operation) on the heater 217b by the heater power regulator 276 and an impedance adjusting operation by the variable impedance regulator 275 via the process system controller 221, the I/O port 221d and the signal line C. Further, for example, the CPU 221a may be configured to be capable of controlling the operations such as an open/closing operation of the gate valve 244 via the process system controller 221, the I/O port 221d and the signal line D. Further, for example, the CPU 221a may be configured to be capable of controlling the operations such as a controlling operation of the RF sensor 272, the matcher 274 and the high frequency power supply 273 via the process system controller 221, the I/O port 221d and the signal line E. Further, for example, the CPU 221a may be configured to be capable of controlling the operations such as gas flow rate adjusting operations of the MFCs 252a, 252b and 252c and opening and closing operations of the valves 253a, 253b, 253c and 243a via the process system controller 221, the I/O port 221d and the signal line F.

The controller 10 may be embodied by installing the above-described program stored in the external memory (for example, a semiconductor memory such as a USB memory and a memory card) 225 into a computer. The memory 221c and the external memory 225 may be embodied by a non-transitory computer readable recording medium. Hereafter, the memory 221c and the external memory 225 may be collectively or individually referred to as a “recording medium”. In the present specification, the term “recording medium” may refer to the memory 221c alone, may refer to the external memory 225 alone, and may refer to both of the memory 221c and the external memory 225. In addition, the program may be provided to the computer by using a communication structure such as the Internet and a dedicated line without using the external memory 225.

### <Measurer, Calculator, Determinator and Setter>

The measurer 31c shown in FIG. 3 measures a weight of the wafer 200 or an amount of the warpage of the wafer 200 before the processing of the wafer 200 starts and after the processing of the wafer 200 ends. For example, the “mass” of the wafer 200 may refer to the mass of the wafer 200 calculated from the weight of the wafer 200 measured by a weight scale (which is a weight meter) 32 or may refer to the mass of the wafer 200 calculated from the amount of the warpage (also referred to as a “warpage amount”) of the wafer 200 measured by the weight scale 32.

When the mass is calculated from the weight of the wafer 200, the measurer 31c measures the weight of the wafer 200 before the processing of the wafer 200 starts and after the processing of the wafer 200 ends, by using the weight scale 32 (see FIG. 1) provided in the vacuum transfer chamber TM. Then, the mass is determined from a difference in the measured weight of the wafer 200 before the start of the processing and after the end of the processing. For example, as shown in FIG. 2, the weight scale 32 may be arranged below the wafer lift pins 266 provided at a lower portion of the process chamber 201. When the susceptor 217 is lowered, the wafer 200 is supported by the wafer lift pins 266. In such a state, the weight of the wafer 200 is transmitted to the weight scale 32 via the wafer lift pins 266.

Alternatively, when the mass is calculated from the warpage amount of the wafer 200, the measurer 31c measures the warpage amount of the wafer 200 before the processing of the wafer 200 starts and after the processing of the wafer 200 ends, by using a warpage amount meter 34 provided in the vacuum transfer chamber TM. Then, the mass is determined from a difference in the measured warpage amount of the wafer 200 before the start of the processing and after the end of the processing. The warpage amount meter 34 is a measuring structure configured to optically measure the warpage amount of the wafer 200. For example, the warpage amount meter 34 is provided at the same position as the weight scale 32 in the vacuum transfer chamber TM (see FIG. 1).

A timing at which the measurer 31c measures the mass may differ depending on the processing of the wafer 200. For example, the timing of measuring the mass may differ depending on a recipe with a high temperature sensitivity and a recipe with a low temperature sensitivity. Further, the timing is stored as a parameter in the memory 221c.

The measurer 31c may measure the mass in situ. Specifically, the measurer 31c may measure the mass within the vacuum transfer chamber TM or the process chamber 201, in other words, under the reduced pressure state, as described above.

A measurement of the mass may be performed every time the processing of the wafer 200 is performed, or may be performed at a predefined timing of the processing of the wafer 200. For example, the measurement of the mass may be performed after the substrate processing is preformed a plurality of times. For example, the mass measured in a manner described above may be stored in the memory 221c.

The calculator 226 may calculate a difference in the mass after the processing of the wafer 200 is performed at least twice. In other words, the mass may be measured during a first execution of the processing of the wafer 200 and during a second execution of the processing of the wafer 200, and the calculator 226 may calculate the difference. Further, the calculator 226 may calculate a thickness value of a film (which has changed during the substrate processing) or an oxidation amount, based on the mass and an area of the wafer 200. Hereinafter, the thickness value of the film may also be referred to as a “film thickness value”.

The determinator 228 determines whether the film thickness value calculated by the calculator 226 is abnormal. As an example, the determinator 228 determines that the film thickness value is abnormal (that is, there is an abnormality) when the film thickness value calculated as described above is equal to or greater than a threshold value which is predefined. The memory 221c stores the film thickness value when the determinator 228 determines that there is the abnormality.

The setter 227 is a structure capable of setting the process conditions. The setter 227 changes the process conditions based on the film thickness value calculated as described above and the threshold value. For example, the process conditions to be changed by the setter 227 may include an output setting value of a heater (for example, the heater 217b) provided in the process chamber 201. The setter 227 may directly change the output setting value of the heater based on the film thickness value calculated as described above and the threshold value.

The controller 10 is configured to be capable of controlling the setter 227 to change the process conditions when the determinator 228 determines that the film thickness value is abnormal.

### (2) Substrate Processing

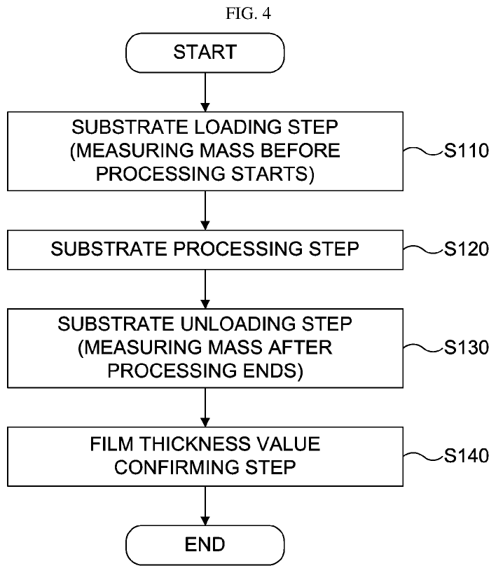

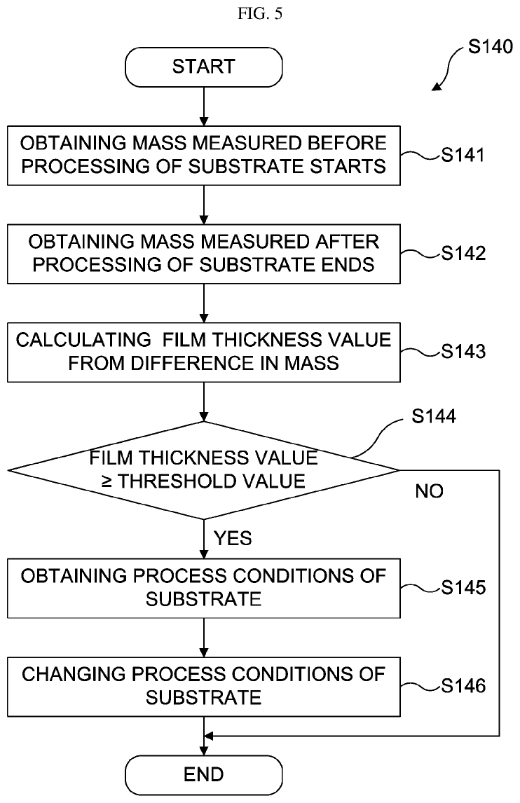

Subsequently, the substrate processing according to the present embodiments will be described mainly with reference to FIGS. 4 and 5. The substrate processing according to the present embodiments (which is a part of a manufacturing process of a semiconductor device such as a flash memory) is performed by using the substrate processing apparatus 100 described above. In the following description, operations of components constituting the substrate processing apparatus 100 are controlled by the controller 10. For example, in the substrate processing according to the present embodiments, an oxidation process is performed on the surface of the wafer 200. For example, a diameter of the wafer 200 is 300 mm. However, the diameter of the wafer 200 may be 200 mm or 450 mm.

The manufacturing process of the semiconductor device (that is, the substrate processing) according to the present embodiments shown in FIG. 4 may include: a step of transferring (loading) the wafer 200 serving as the substrate and measuring the mass of the wafer 200 before the processing of the wafer 200 starts (that is, a substrate loading step S110); a step of performing the processing the wafer 200 in accordance with the process conditions of the wafer 200 (that is, a substrate processing step S120); a step of transferring (unloading) the wafer 200 and measuring the mass of the wafer 200 after the processing of the wafer 200 ends (that is, a substrate unloading step S130); and a step of confirming the film thickness value (that is, a film thickness value confirming step S140).

The film thickness value confirming step S140 is performed in accordance with a process flow shown in FIG. 5. Specifically, the step S140 includes: steps S141, S142 and S143 of calculating the film thickness value from the difference in the mass obtained before and after the processing of the wafer 200 serving as the substrate in the step S110 and the step S130; a step S144 of determining whether the film thickness value is abnormal; a step of setting the process conditions (not shown); and steps S145 and S146 of changing the process conditions when it is determined that the film thickness value is abnormal.

### <Substrate Loading Step S110>

First, in FIG. 1, for example, the wafer 200 is taken out from the load lock chambers LM1 and LM2 by the vacuum robot VR, and placed on the weight scale 32. Thereby, the mass before the processing of the wafer 200 starts (specifically the mass of the wafer 200) is measured. After the mass of the wafer 200 is measured, the wafer 200 is transferred (loaded) from the vacuum transfer chamber TM to the process chamber 201 of the process module PM (for example, the process module PM1) using the vacuum robot VR.

In FIG. 2, the susceptor 217 is lowered to a position of transferring the wafer 200 by the susceptor elevator 268 such that the wafer lift pins 266 pass through the through-holes 217a of the susceptor 217. As a result, the wafer lift pins 266 protrude from the through-holes 217a by a predetermined height above a surface of the susceptor 217.

Subsequently, the gate valve 244 corresponding to the gate valve PGV (that is, the gate valves PGV1, PGV2, PGV3 and PGV4 shown in FIG. 1) shown in FIG. 1 is opened, and the wafer 200 is transferred into the process chamber 201 using the transfer structure (that is, the vacuum robot VR shown in FIG. 1) from the vacuum transfer chamber TM provided adjacent to the process chamber 201. As a result, the wafer 200 loaded into the process chamber 201 is placed on and supported by the wafer lift pins 266 (which protrude from the surface of the susceptor 217) in a horizontal orientation. After the wafer 200 is loaded into the process chamber 201, the transfer structure (that is, the vacuum robot VR shown in FIG. 1) is retracted to a position outside the process chamber 201, and the gate valve 244 is closed to hermetically seal (or close) the inside of the process chamber 201. Thereafter, the susceptor elevator 268 elevates the susceptor 217 to a predetermined position between a lower end 203a of the resonance coil 212 and an upper end 245a of the loading/unloading port 245. As a result, the wafer 200 is supported on an upper surface of the susceptor 217. For example, the substrate loading step S110 may be performed while purging the inside of the process chamber 201 with the inert gas or the like.

### <Substrate Processing Step S120>

For example, the substrate processing step S120 may include: a temperature elevation and vacuum exhaust step; a reactive gas supply step; a plasma processing step; and a vacuum exhaust step.

### <Temperature Elevation and Vacuum Exhaust Step>

Subsequently, a temperature of the wafer 200 loaded into the process chamber 201 is elevated. The heater 217b is heated in advance, and the wafer 200 is heated to a predetermined temperature (for example, a temperature within a range from 150° C. to 650° C., that is, equal to or higher than 150° C. and equal to or lower than 650° C.) by placing the wafer 200 on the susceptor 217 where the heater 217b is embedded. For example, in the present step, the wafer 200 is heated such that the temperature of the wafer 200 reaches and is maintained at 600° C. Further, while the wafer 200 is being heated, the vacuum pump 246 vacuum-exhausts an inner atmosphere of the process chamber 201 through the gas exhaust pipe 231 such that an inner pressure of the process chamber 201 reaches and is maintained at a predetermined pressure (for example, a pressure within a range from 0.1 Pa to 1,000 Pa). For example, in the present step, the vacuum pump 246 vacuum-exhausts the inner atmosphere of the process chamber 201 such that the inner pressure of the process chamber 201 reaches and is maintained at 200 Pa. The vacuum pump 246 may be continuously operated at least until the substrate unloading step S130 described later is completed.

### <Reactive Gas Supply Step>

Subsequently, as a supply of the reactive gas, a supply of the O₂ gas is started. Specifically, the valve 253a is opened to start the supply of the O₂ gas into the process chamber 201 through the buffer chamber 237 while a flow rate of the O₂ gas is adjusted by the MFC 252a. In the reactive gas supply step, for example, the flow rate of the O₂ gas is adjusted (or set) to a predetermined value within a range from 100 seem to 1,000 seem. In addition, for example, the inner atmosphere of the process chamber 201 is exhausted by adjusting the opening degree of the APC valve 242 such that the inner pressure of the process chamber 201 reaches and is maintained at a predetermined pressure within a range from 1 Pa to 1,000 Pa. While appropriately exhausting the inner atmosphere of the process chamber 201 as described above, the 02 gas is continuously supplied into the process chamber 201 until the plasma processing step described later is completed.

### <Plasma Processing Step>

When the inner pressure of the process chamber 201 is stabilized, a supply of the high frequency power to the resonance coil 212 is started from the high frequency power supply 273 through the matcher 274.

Thereby, a high frequency electric field is formed in the plasma generation space 201a. As a result, a donut-shaped induction plasma is excited by the high frequency electric field at a height corresponding to the electrical midpoint of the resonance coil 212 in the plasma generation space 201a. The O₂ gas is excited into a plasma state and dissociates. As a result, reactive species containing oxygen such as oxygen active species and oxygen ions can be generated.

As described above, the standing wave in which the phase voltage thereof and the opposite phase voltage thereof are always canceled out by each other is generated, and the highest phase current is generated at the electrical midpoint of the resonance coil 212 (the node with zero voltage). The donut-shaped induction plasma excited at the electrical midpoint is hardly capacitively coupled with the walls of the process chamber 201 or the substrate mounting table. That is, the donut-shaped induction plasma whose electric potential is extremely low is generated in the plasma generation space 201a.

As described above, since the power supply controller provided at the high frequency power supply 273 compensates for the deviation of the resonance point of the resonance coil 212 due to the variation in the capacitive coupling or the inductive coupling of the plasma, it is possible to more accurately form the standing wave accurately. Therefore, the plasma which is almost not capacitively coupled and whose electric potential is extremely low can be more reliably generated in the plasma generation space 201a.

Since the donut-shaped induction plasma whose electric potential is extremely low is generated, it is possible to prevent a sheath from being generated on walls of the process chamber 201 or the substrate mounting table. As a result, according to the present embodiments, the ions in the plasma are not accelerated.

The oxygen radicals generated by the induction plasma and non-accelerated ions are supplied onto the wafer 200 placed on the susceptor 217 in the substrate processing space 201b. Thereby, the film formed on the wafer 200 (for example, a silicon film) is modified into a silicon oxide film whose step coverage is good. In addition, an ion attack due to acceleration can be prevented. Thereby, it is possible to suppress a wafer damage caused by the ions.

For example, it is possible to prevent the acceleration of the ions. Thereby, there is no sputtering effect on a peripheral wall of the plasma generation space 201a. Further, no damage is caused to the peripheral wall of the plasma generation space 201a. As a result, it is possible to improve a lifetime of the substrate processing apparatus 100. In addition, it is possible to prevent a problem of contaminating the wafer 200 due to constituents of the plasma generation space 201a being mixed into the plasma.

In addition, the power supply controller provided at the high frequency power supply 273 compensates for the reflected wave power due to an impedance mismatch generated in the resonance coil 212 by adjusting the power supplied from the high frequency power supply 273, and compensates for a decrease in an effective load power. Thereby, it is possible to supply the high frequency power maintained at an initial level to the resonance coil 212 reliably, and it is also possible to stabilize the plasma. Accordingly, the wafer held in the substrate processing space 201b can be processed uniformly at a constant rate.

After a predetermined process time (for example, 10 seconds to 300 seconds) has elapsed, the supply of the high frequency power from the high frequency power supply 273 is stopped to stop a plasma discharge in the process chamber 201. In addition, the valve 253a is closed to stop the supply of the O₂ gas into the process chamber 201. Thereby, the plasma processing step is completed.

### <Vacuum Exhaust Step>

After the supply of the O₂ gas is stopped in the plasma processing step, the inner atmosphere of the process chamber 201 is vacuum-exhausted through the gas exhaust pipe 231. Thereby, a gas such as the O₂ gas and an exhaust gas generated from a reaction of the O₂ gas in the process chamber 201 can be exhausted out of the process chamber 201. Thereafter, the opening degree of the APC valve 242 is adjusted such that the inner pressure of the process chamber 201 is adjusted to substantially the same pressure (for example, 100 Pa) as that of the vacuum transfer chamber TM (to which the wafer 200 is to be transferred) provided adjacent to the process chamber 201.

### <Substrate Unloading Step S130>

After the inner pressure of the process chamber 201 is adjusted to a predetermined pressure, the susceptor 217 is lowered to the position of transferring the wafer 200 until the wafer 200 is supported by the wafer lift pins 266. Then, the gate valve 244 is opened, and the wafer 200 is transferred (unloaded) from the process chamber 201 to the vacuum transfer chamber TM by using the vacuum robot VR. For example, the wafer 200 may be unloaded while purging the inside of the process chamber 201 with the inert gas or the like. Then, the wafer 200 is placed on the weight scale 32, and the mass after the processing of the wafer 200 ends (specifically the mass of the wafer 200) is measured.

### <Film Thickness Value Confirming Step S140>

The calculator 226 calculates the film thickness value from the difference in the mass obtained before and after the processing of the wafer 200 (the steps S141, S142 and S143). Specifically, the calculator 226 calculates the film thickness value increased during the substrate processing from the difference in the mass and the area of the wafer 200. The film thickness value is stored in the memory 221c. Thereby, the determinator 228 can acquire the film thickness value from the memory 221c.

The determinator 228 determines whether the film thickness value is equal to or greater than the threshold value which is predefined. When the film thickness value is equal to or greater than the threshold value, the determinator 228 determines that there is the abnormality. The controller 10 temporarily puts the process chamber 201 determined to be abnormal in a standby state. Then, the controller 10 controls the setter 227 to control an output of the heater 217b in accordance with an oxidation amount (or the film thickness value) and an output correction value of the heater 217b (see FIG. 2), which are predefined by parameters and the like (the step S145). Thereby, the controller 10 changes the inner temperature of the process chamber 201 (the step S146). When the inner temperature of the process chamber 201 reaches and is maintained at a desired temperature, the standby state is canceled and the processing of the wafer 200 is resumed. Therefore, it is possible to prevent the substrate processing from being performed while the inner temperature of the process chamber 201 that has been determined to be abnormal is being controlled.

In the step S144 of determining whether the film thickness value is abnormal, when the film thickness value is less than the threshold value, the determinator 228 determines that the film thickness value is normal. Therefore, the process conditions are not changed.

### (3) Program

A program according to the present embodiments is a program that causes, by the computer, the substrate processing apparatus 100 to perform: (a) transferring the substrate; (b) performing the processing of the substrate in accordance with the process conditions of the substrate; (c) measuring the mass of the substrate before the processing of the substrate starts and after the processing of the substrate ends; (d) calculating the film thickness value of the substrate from the difference in the mass obtained before and after the processing of the substrate; (e) determining whether the film thickness value obtained in (d) is abnormal; (f) setting the process conditions; and (g) changing the process conditions when it is determined that the film thickness value is abnormal in (e).

For example, the program may be provided (or distributed) as a non-transitory computer-readable recording medium on which the program is recorded. Further, the program may be a program recorded on a non-transitory computer-readable recording medium.

### (4) Effects According to Present Embodiments

According to the present embodiments, it is possible to obtain one or more of the following effects. From the difference in the mass obtained before and after the processing of the wafer 200 serving as the substrate, it is possible to calculate a thickness (that is, the film thickness value) of a coating film (that is, the film) formed on the wafer 200 formed by the substrate processing. In addition, it is possible to determine a presence or absence of the abnormality based on the film thickness value. When it is determined that there is the abnormality, the heater 217b is automatically corrected to prevent incorrect settings by an operator. Further, by automatically correcting the heater 217b, it is possible to obtain a target oxidation amount (that is, a target film thickness value) even when a thermal emissivity of the susceptor cover 229 changes over time.

### Other Embodiments of Present Disclosure

While the technique of the present disclosure is described in detail by way of the embodiments described above, the technique of the present disclosure is not limited thereto. The technique of the present disclosure may be modified in various ways without departing from the scope thereof.

For example, the technique of the present disclosure may also be applied to not only the oxidation process but also other process such as an oxynitridation process (in which the oxidation process and a nitridation process are performed together), a diffusion process, a film-forming process (a film deposition process) and an etching process. The reactive gas to be used in each process exemplified above may be appropriately selected depending on the contents of each process. For example, in the oxynitridation process, the oxygen-containing gas such as oxygen (O₂) gas alone may be used, or a mixed gas in which a nitrogen-containing gas, the hydrogen-containing gas such as hydrogen (H₂) gas and a rare gas is added to the oxygen-containing gas may be used. For example, in the film-forming process, a silicon-containing gas such as monosilane (SiH₄) gas or disilane (Si₂H₆) gas in combination with the oxygen-containing gas or the nitrogen-containing gas may be used. As a result, it is possible to perform not only the oxidation process (which is anisotropic or isotropic) but also the nitridation process, the oxynitridation process, the diffusion process, the film-forming process and the etching process (which are anisotropic or isotropic). For example, when the mixed gas (which is a mixture of two or more gases) is supplied, the two or more gases may be mixed (pre-mixed) in a supply pipe and then supplied into the process chamber 201, or the two or more gases may be separately supplied to the process chamber 201 through different supply pipes and mixed (post-mixed) within the process chamber 201.

For example, the embodiment described above are described by way of an example in which a single wafer type substrate processing apparatus capable of processing one or several substrates at once is used to form the film. However, the technique of the present disclosure is not limited thereto. For example, the technique of the present disclosure may be preferably applied when a vertical batch type substrate processing apparatus capable of simultaneously processing a plurality of substrates is used to form the film. The process sequences and the process conditions of each process using the substrate processing apparatuses exemplified above may be substantially the same as those of the embodiments described above.

It is preferable that the process recipe (that is, a program defining parameters such as the process sequences and the process conditions of the substrate processing) used to form various films is prepared individually in accordance with the contents of the substrate processing such as a type of the film to be formed, a composition ratio of the film, a quality of the film, a thickness of the film, the process sequences and the process conditions of the substrate processing. That is, a plurality of process recipes are prepared. When starting the substrate processing, an appropriate process recipe is preferably selected among the process recipes in accordance with the contents of the substrate processing. Specifically, it is preferable that the process recipes prepared individually in accordance with the contents of the substrate processing are stored (installed) in the memory 221c of the substrate processing apparatus 100 in advance via an electric communication line or the recording medium (for example, the external memory 225) storing the process recipes. Then, when starting the substrate processing, the CPU 221a of the substrate processing apparatus 100 preferably selects the appropriate process recipe among the process recipes stored in the memory 221c of the substrate processing apparatus 100 in accordance with the contents of the substrate processing. Thus, various films of different types, different composition ratios, different qualities and different thicknesses may be universally formed with a high reproducibility using a single substrate processing apparatus. In addition, since a burden on the operator such as inputting the process sequences and the process conditions may be reduced, various processes can be performed quickly while avoiding a malfunction of the substrate processing apparatus 100.

The technique of the present disclosure may be implemented by changing an existing process recipe stored in the substrate processing apparatus 100 to a new process recipe. When changing the existing process recipe to the new process recipe, the new process recipe may be installed in the substrate processing apparatus 100 via the electric communication line or the recording medium storing the process recipes. Alternatively, the existing process recipe already stored in the substrate processing apparatus 100 may be directly changed to the new process recipe according to the technique of the present disclosure by operating the input/output device of the substrate processing apparatus 100.

For example, in the present specification, the “temperature” may refer to the temperature of the wafer 200 or an inner temperature of the process chamber 201, and the “pressure” may refer to the inner pressure of the process chamber 201. In addition, the “process time” refers to a time duration of continuously performing a process related thereto.

Further, in the present specification, the term “wafer” may refer to “a wafer itself”, or may refer to “a wafer and a stacked structure (aggregated structure) of a predetermined layer (or layers) or a film (or films) formed on a surface of the wafer”. In the present specification, the term “a surface of a wafer” may refer to “a surface of a wafer itself”, or may refer to “a surface of a predetermined layer (or a predetermined film) formed on a wafer”. In the present specification, the terms “substrate” and “wafer” may be used as substantially the same meaning.

For example, the embodiments described above are described by way of an example in which a substrate processing apparatus including a cold wall type process furnace is used to form the film. However, the technique of the present disclosure is not limited thereto. For example, the technique of the present disclosure may be preferably applied when a substrate processing apparatus including a hot wall type process furnace is used to form the film.

Further, the embodiments described above and modified examples described above may be appropriately combined. The process sequences and the process conditions of each combination thereof may be substantially the same as those of the embodiments or modified examples described above. The process sequences and the process conditions of each process using the substrate processing apparatuses exemplified above may be substantially the same as those of the embodiments described. Even in such a case, it is possible to obtain substantially the same effects as in the embodiments or modified examples described above.

According to some embodiments of the present disclosure, it is possible to suppress fluctuations in substrate processing results over time due to the operations of the substrate processing apparatus.

What is claimed is:

1. A substrate processing apparatus comprising:
a transfer chamber to which or from which a substrate is transferred;
a process chamber in which a processing of the substrate is performed in accordance with process conditions of the substrate;
a measurer configured to measure a mass of the substrate before the processing of the substrate starts and after the processing of the substrate ends;
a calculator configured to calculate a film thickness value of the substrate from a difference in the mass measured by the measurer before the processing starts and after the processing ends;
a determinator configured to determine whether the film thickness value calculated by the calculator is abnormal;
a setter configured to set the process conditions; and
a controller configured to be capable of controlling the setter to change the process conditions when the determinator determines that the film thickness value is abnormal.

2. The substrate processing apparatus of claim 1, wherein the measurer is further configured to measure the mass of the substrate before the processing of the substrate starts and after the processing of the substrate ends by using a weight scale provided in the transfer chamber.

3. The substrate processing apparatus of claim 1, wherein the measurer is further configured to measure the mass of the substrate before the processing of the substrate starts and after the processing of the substrate ends by using a warpage amount meter provided in the transfer chamber.

4. The substrate processing apparatus of claim 1, further comprising
a memory in which the difference is stored,
wherein the controller is further configured to be capable of controlling the memory to store the difference.

5. The substrate processing apparatus of claim 4, wherein the calculator is further configured to calculate the film thickness value which has changed during the processing of the substrate based on the difference and an area of the substrate.

6. The substrate processing apparatus of claim 5, wherein the determinator is further configured to determine that the film thickness value is abnormal when the film thickness value calculated by the calculator is equal to or greater than a threshold value which is predefined.

7. The substrate processing apparatus of claim 6, wherein the memory is configured to store the film thickness value when the determinator determines that the film thickness value is abnormal.

8. The substrate processing apparatus of claim 6, wherein the setter is further configured to change the process conditions based on the film thickness value calculated by the calculator and the threshold value.

9. The substrate processing apparatus of claim 8, wherein the process conditions to be changed by the setter comprise an output setting value of a heater provided in the process chamber.

10. The substrate processing apparatus of claim 8, wherein the setter is further configured to change an output setting value of a heater provided in the process chamber based on the film thickness value calculated by the calculator and the threshold value.

11. The substrate processing apparatus of claim 1, wherein a timing at which the measurer measures the mass of the substrate differs depending on the processing of the substrate.

12. The substrate processing apparatus of claim 11, wherein the timing at which the measurer measures the mass of the substrate is stored as a parameter in a memory.

13. The substrate processing apparatus of claim 1, wherein the measurer is further configured to measure the mass of the substrate in situ.

14. The substrate processing apparatus of claim 1, wherein the measurer is further configured to measure the mass of the substrate under a reduced pressure state.

15. The substrate processing apparatus of claim 1, wherein the measurer is further configured to measure the mass of the substrate every time the processing of the substrate is performed.

16. The substrate processing apparatus of claim 1, wherein the measurer is further configured to measure the mass of the substrate at a predefined timing of the processing of the substrate.

17. A method of manufacturing a semiconductor device, comprising:
(a) transferring a substrate;
(b) performing a processing of the substrate in accordance with process conditions of the substrate;
(c) measuring a mass of the substrate before the processing of the substrate starts and after the processing of the substrate ends;
(d) calculating a film thickness value of the substrate from a difference in the mass of the substrate measured before the processing starts and after the processing ends in (c);
(e) determining whether the film thickness value calculated in (d) is abnormal;
(f) setting the process conditions; and
(g) changing the process conditions when it is determined that the film thickness value is abnormal in (e).

18. A non-transitory computer-readable recording medium storing a program that causes a substrate processing apparatus, by a computer, to perform:
(a) transferring a substrate;
(b) performing a processing of the substrate in accordance with process conditions of the substrate;
(c) measuring a mass of the substrate before the processing of the substrate starts and after the processing of the substrate ends;
(d) calculating a film thickness value of the substrate from a difference in the mass of the substrate measured before the processing starts and after the processing ends in (c);
(e) determining whether the film thickness value calculated in (d) is abnormal;
(f) setting the process conditions; and
(g) changing the process conditions when it is determined that the film thickness value is abnormal in (e).
